(19) United States
(12) Patent Application Publication
(10) Pub. No.: US 2015/0051869 A1
(43) Pub. Date: Feb. 19, 2015

(54) METHOD FOR RELATING TEST TIME AND ESCAPE RATE FOR MULTIVARIATE ISSUE

(71) Applicant: International Business Machines Corporation, Armonk, NY (US)

(72) Inventors: Jennifer E. Appleyard, Arlington, VA (US); Nathaniel R. Chadwick, Lowell, MA (US); William P. Hovis, Rochester, MN (US)

(73) Assignee: International Business Machines Corporation, Armonk, NY (US)

(21) Appl. No.: 13/968,760

(22) Filed: Aug. 16, 2013

(51) Int. Cl. G01R 31/26; G06F 17/50; G04F 13/00

(52) U.S. Cl. CPC G01R 31/2601; G04F 13/00; G06F 17/5009
USPC 702/176; 703/2

(57) ABSTRACT

Various embodiments provide systems, computer program products and computer implemented methods. Some embodiments include a system for modeling a relationship between a test time and a defect rate for a systematic multivariate issue caused by at least one predictable component and a random component in a semiconductor testing environment, the multivariate issue causing failure of a semiconductor device, the system that includes at least one computing device configured to perform actions including quantifying the at least one predictable component to produce at least one first mathematical form, quantifying the random component using distribution functions to produce a second mathematical form and producing a mathematical model of a relationship between the test time and the defect rate at a test condition by mathematically combining the at least one first mathematical form and the second mathematical form.

### FIELD

The subject matter disclosed herein relates generally to semiconductor testing. More particularly, the subject matter disclosed relates to methods, computer program products and systems for predicting relationships between aspects of semiconductor device fabrication failure rates.

### BACKGROUND

In general, semiconductor devices are subject to unique failure modes, which can lead to defective parts. The failure modes are difficult to detect, and are caused by the interaction of multiple effects. Once the failure modes are detected in the development cycle, tests and procedures are established to prevent the unique failure modes from continuing through the product supply line. Defect rates may be measured in units of defective parts per million, (DPPM). The time it takes for a defective part to fail (time to fail, or TTF) is an important piece of establishing such a test. Technicians may employ excess test conditions in order to determine DPPM or TTF empirically. Such excess test conditions may include alteration of test time, voltage (within safe operating voltage of the device), frequency, test sequences, etc.

Other conventional methods of extrapolating defect rate or escape rate involve predictions that are based on defect density models.

### BRIEF DESCRIPTION

Various embodiments provide systems, computer program products and computer implemented methods. Some embodiments include a system for modeling a relationship between a test time and a defect rate for a systematic multivariate issue caused by at least one predictable component and a random component in a semiconductor testing environment, the multivariate issue causing failure of a semiconductor device, the system that includes at least one computing device configured to perform actions including quantifying the at least one predictable component to produce at least one first mathematical form, quantifying the random component using distribution functions to produce a second mathematical form and producing a mathematical model of a relationship between the test time and the defect rate at a test condition by mathematically combining the at least one first mathematical form and the second mathematical form.

A first aspect provides a system for modeling a relationship between a test time and a defect rate for a systematic multivariate issue caused by at least one predictable component and a random component in a semiconductor testing environment, the multivariate issue causing failure of a semiconductor device, the system comprising: at least one computing device configured to perform actions including: quantifying the at least one predictable component to produce at least one first mathematical form; quantifying the random component using distribution functions to produce a second mathematical form; and producing a mathematical model of a relationship between the test time and the defect rate at a test condition by mathematically combining the at least one first mathematical form and the second mathematical form.

A second aspect provides a computer program product comprising program code stored on a computer-readable storage medium, which when executed by at least one computing device, enables the at least one computing device to implement a method of modeling relationship between a test time and a defect rate for a systematic multivariate issue caused by at least one predictable component and a random component in a semiconductor testing environment, the multivariate issue causing failure of a semiconductor device, configured to perform actions including: quantifying the at least one predictable component to produce at least one first mathematical form; quantifying the random component using distribution functions to produce a second mathematical form; and producing a mathematical model of a relationship between the test time and the defect rate at a test condition by mathematically combining the at least one first mathematical form and the second mathematical form.

A third aspect provides a system for calculating a test time and an escape rate for a multivariate issue in a semiconductor testing environment, the multivariate issue being caused by at least one predictable component and a random component, the multivariate issue causing failure of a semiconductor device, the system comprising: at least one computing device configured to perform actions including: quantifying an occurrence of the multivariate issue based on a manufacturing variability; developing a mathematical model of the occurrence of the multivariate issue across at least one expected manufacturing process parameter for the semiconductor device; determining, for the semiconductor device, a time-to-fail quantification by grouping dependency of occurrence of the multivariate issue versus a range of a plurality of process parameters; quantifying detection of the multivariate issue across a plurality of application conditions for a set of semiconductor components, the set of semiconductor components having a variable time-to-fail; generating a mathematical distribution model of time-to-fail for at least one failing semiconductor component from the set of semiconductor components, for the plurality of application conditions; generating a model of time-to-fail distribution across the expected manufacturing process parameters for the plurality of application conditions using the time-to-fail quantification, the mathematical model of occurrence and the mathematical distribution model of time-to-fail; and calculating the test time and the escape rate for the multivariate issue using the generated model of time-to-fail distribution.

### BRIEF DESCRIPTION OF THE DRAWINGS

These and other features of this invention will be more readily understood from the following detailed description of the various aspects of the invention taken in conjunction with the accompanying drawings that depict various embodiments of the invention, in which:

FIG. 1 depicts an exemplary environment according to embodiments.

FIG. 2 shows an exemplary bar graph and exemplary data according to various embodiments.

FIG. 3 shows an exemplary graph according to various embodiments.

FIG. 4 shows an exemplary graph according to various embodiments.

FIG. 5 shows an exemplary graph of data according to various embodiments.

FIG. 6 shows an exemplary bar graph of data according to various embodiments.

FIG. 7 shows an exemplary bar graph and exemplary data according to various embodiments.

FIG. 8 shows a flow diagram illustrating a method according to various embodiments.

FIG. 9 shows an exemplary graph according to various embodiments.

FIG. 10 shows a flow diagram illustrating a method according to various embodiments.

It is noted that the drawings of the invention are not to scale. The drawings are intended to depict only typical aspects of the invention, and therefore should not be considered as limiting the scope of the invention. In the drawings, like numbering represents like elements between the drawings.

### DETAILED DESCRIPTION OF THE INVENTION

The subject matter disclosed herein relates generally to semiconductor testing. More specifically, the disclosure provided herein relates to methods, computer program products and systems for predicting relationships between aspects of semiconductor device fabrication failure rates.

As described herein, defects in semiconductor devices created during fabrication are conventionally measured empirically. Embodiments described herein allow for prediction of a minimum test time required to achieve a target escape rate for a specific, multivariate systematic, having at least one predictable component and a random component. It should be understood that “random” is meant to be a random event, such as noise or another low-likelihood, unpredictable event. Embodiments further allow for prediction of minimum test time required to achieve target escape rate for a specific systematic that is multivariate, having predictable components and a random component. It should be understood that the components designated as predictable, vary across a manufacturing process. In some instances, the predictable component varies across FET strength, but could also vary due to other manufacturing parameters related to FET characteristics such as gate length, on current, threshold voltage, oxide thickness, etc. The predictable component may also vary across wiring characteristics such resistance, capacitance, etc. It should also be understood that the parameters listed are not intended to be limiting of the various embodiments.

Unlike conventional methods for prediction that are based on defect density models, embodiments according to the present disclosure avoid using defect density models.

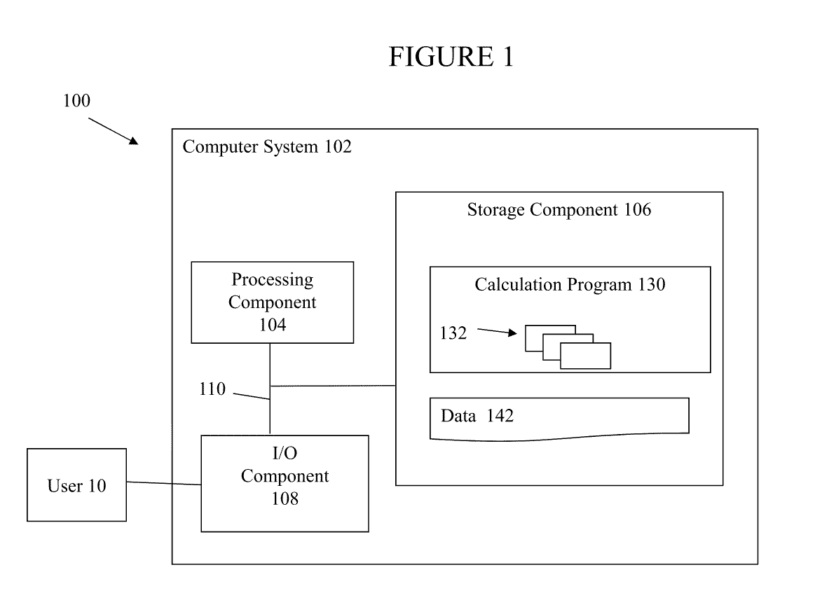

FIG. 1 depicts an exemplary environment according to embodiments. To this extent, the environment 100 includes a computer system 102 that can perform a process described herein in order to perform calculations and to perform other related processes. In particular, the computer system 102 is shown as including a calculation program 130, which makes computer system 102 operable to handle all necessary calculations and functions by performing any/all of the processes described herein and implementing any/all of the embodiments described herein.

The computer system 102 is shown including a processing component 104 (e.g., one or more processors), a storage component 106 (e.g., a storage hierarchy), an input/output (I/O) component 108 (e.g., one or more I/O interfaces and/or devices), and a communications pathway 110. In general, the processing component 104 executes program code, such as the relevance calculation 130, which maybe at least partially fixed in the storage component 106. While executing program code, the processing component 104 can process data, which can result in reading and/or writing transformed data from/to the storage component 106 and/or the I/O component 108 for further processing. The pathway 110 provides a communications link between each of the components in the computer system 102. The I/O component 108 can comprise one or more human I/O devices, which enable a user 10 to interact with the computer system 102 and/or one or more communications devices to enable a system user 10 to communicate with the computer system 102 using any type of communications link. User 10 may be a human, including, but not limited to the user that supplies a query or a raw data source, a different computer user, or a non-human system. Calculation program 130 can manage a set of interfaces (e.g., graphical user interface(s), application program interface, etc.) that enable human and/or system users 10 to interact with calculation program 130. Further, calculation program 130 can manage (e.g., store, retrieve, create, manipulate, organize, present, etc.) data 142, such as issue occurrence data or test time data, etc., using any solution.

In any event, computer system 102 can comprise one or more general purpose computing articles of manufacture (e.g., computing devices) capable of executing program code, such as the calculation program 130, installed thereon. As used herein, it is understood that “program code” means any collection of instructions, in any language, code or notation, that cause a computing device having an information processing capability to perform a particular function either directly or after any combination of the following: (a) conversion to another language, code or notation; (b) reproduction in a different material form; and/or (c) decompression. To this extent, calculation program 130 can be embodied as any combination of system software and/or application software.

Further, the calculation program 130 can be implemented using a set of modules 132. In this case, a module 132 can enable the computer system 102 to perform a set of tasks used by the calculation program 130, and can be separately developed and/or implemented apart from other portions of the calculation program 130. As used herein, the term “component” means any configuration of hardware, with or without software, which implements the functionality described in conjunction therewith using any solution, while the term “module” means program code that enables the computer system 102 to implement the functionality described in conjunction therewith using any solution. When fixed in a storage component 106 of a computer system 102 that includes a processing component 104, a module is a substantial portion of a component that implements the functionality. Regardless, it is understood that two or more components, modules, and/or systems may share some/all of their respective hardware and/or software. Further, it is understood that some of the functionality discussed herein may not be implemented or additional functionality may be included as part of the computer system 102.

When the computer system 112 comprises multiple computing devices, each computing device may have only a portion of calculation program 130 fixed thereon (e.g., one or more modules 132). However, it is understood that the computer system 102 and calculation program 130 are only representative of various possible equivalent computer systems that may perform a process described herein. To this extent, in other embodiments, the functionality provided by the computer system 102 and calculation program 130 can be at least partially implemented by one or more computing devices that include any combination of general and/or specific purpose hardware with or without program code. In each embodiment, the hardware and program code, if included, can be created using standard engineering and programming techniques, respectively.

Regardless, when the computer system 102 includes multiple computing devices, the computing devices can communicate over any type of communications link. Further, while performing a process described herein, the computer system 102 can communicate with one or more other computer systems using any type of communications link. In either case, the communications link can comprise any combination of various types of wired and/or wireless links; comprise any combination of one or more types of networks; and/or utilize any combination of various types of transmission techniques and protocols.

The computer system 102 can obtain or provide data, such data 142 using any solution. For example, the computer system 102 can generate and/or be used to generate data 142, retrieve data 142, from one or more data stores, receive data 142 a, from another system, send 142 to another system, etc.

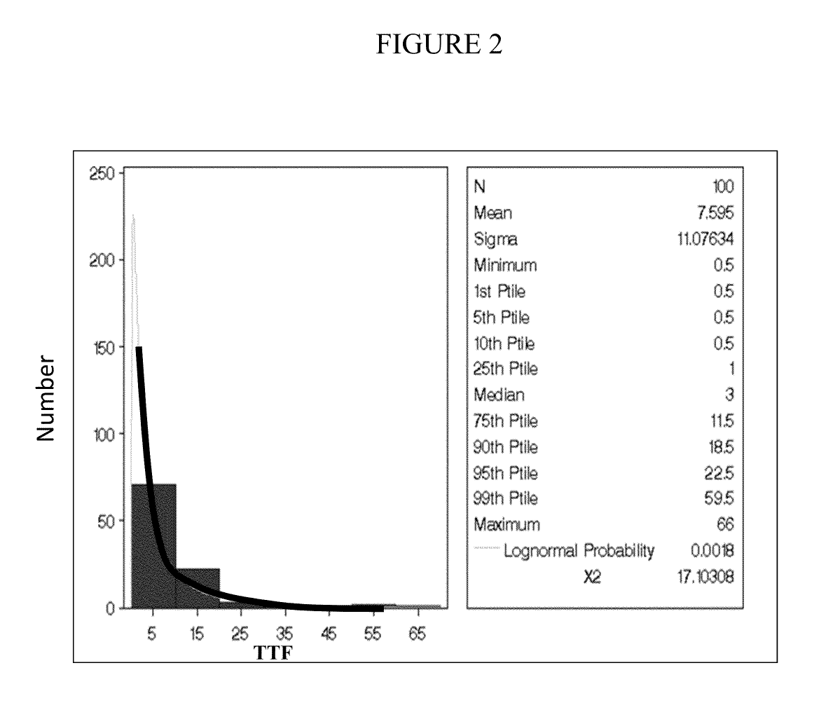

FIG. 2 shows an exemplary bar graph and exemplary data according to various embodiments. This bar graph and extrapolated curve illustrate the variability of time to fail, and that the data is fit by a lognormal distribution of time to fail (TTF) vs. number of test instances for one device tested. The parameters describing this distribution are inputs for the model. It should be understood that variable TTF means that the time in seconds, for a fail to occur, can vary across many instances of testing. It should also be understood that variable TTF dependency may be exponential.

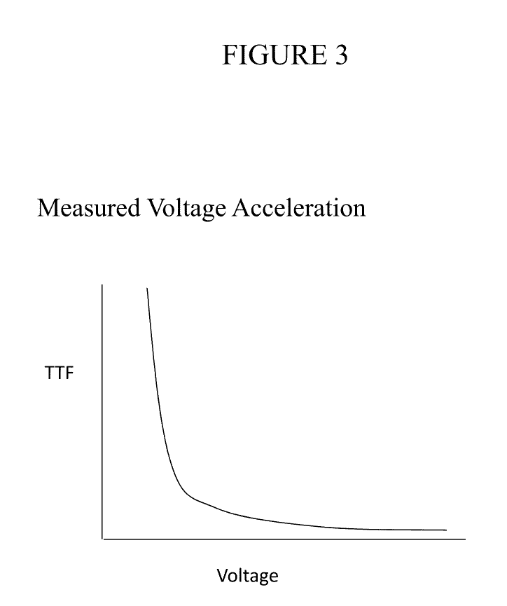

FIG. 3 shows an exemplary graph according to various embodiments. Time to fail is empirically measured on failed devices tested across varying voltages. This graph illustrates the lognormal relationship between TTF vs. voltage for failing devices.

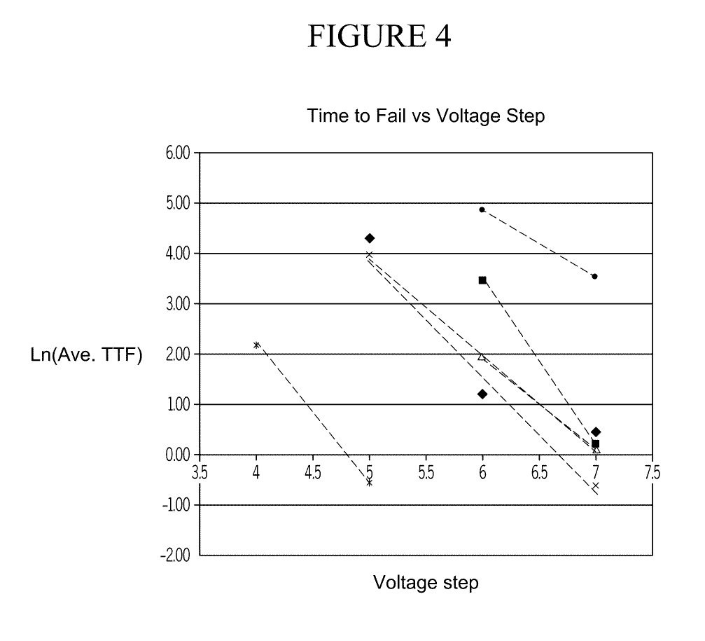

FIG. 4 shows an exemplary graph according to various embodiments. The graph illustrated in FIG. 4 illustrates log linear relationships between voltage and TTF and thus an exponential relationship between TTF and voltage. The equation describing this relationship includes inputs for the model.

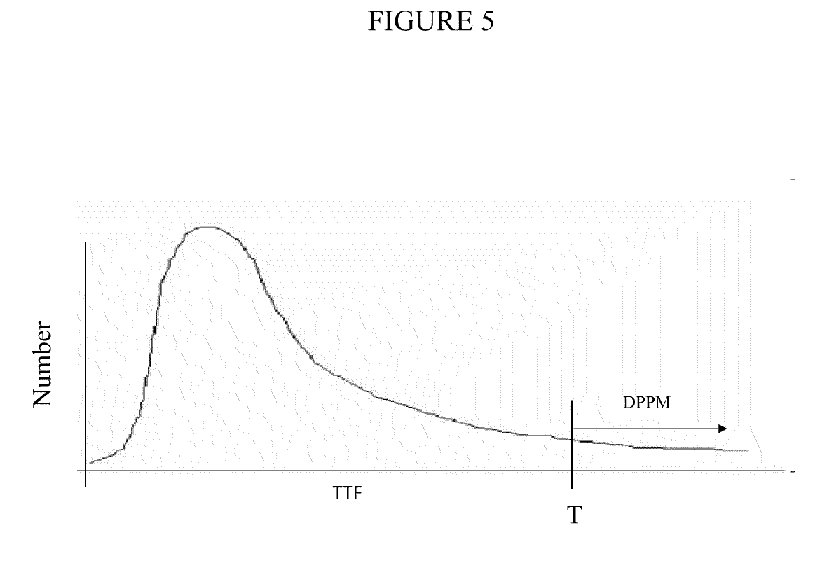

FIG. 5 shows an exemplary graph of data according to various embodiments. This is the output of the model. This graph shows a curve illustrating calculated TTF distribution at one set of test conditions. A threshold T of an acceptable DPPM is shown. This graph illustrates that the methods according to various embodiments may be optimized by DPPM or TTF.

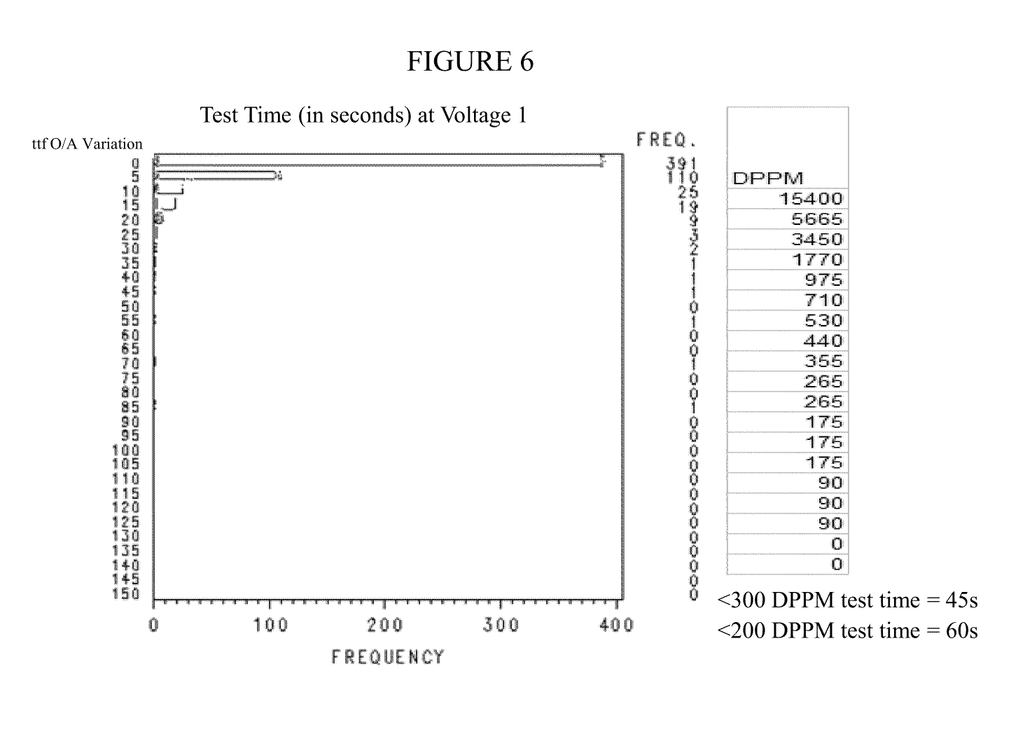

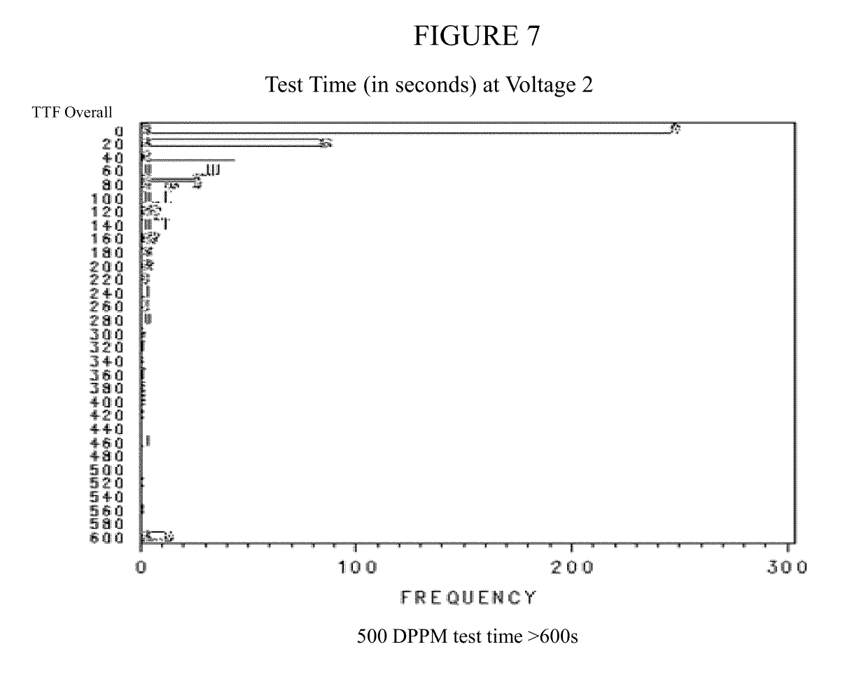

FIGS. 6 and 7 show exemplary bar graphs of data according to various embodiments. FIG. 6 shows a bar graph of frequency of failure vs. TTF at one voltage, V1 and FIG. 7 shows a bar graph of frequency of failure vs. TTF at another voltage, V2. FIG. 6 illustrates less than 300 DPPM when the test time was 45 seconds and less than 200 DPPM when test time was 60 seconds at V1. FIG. 7 illustrates 500 DPPM with test time greater than 600 seconds at V2. For this case, voltage 1 is a more suitable test condition, because it is easier to implement a shorter duration test compared to a long duration test.

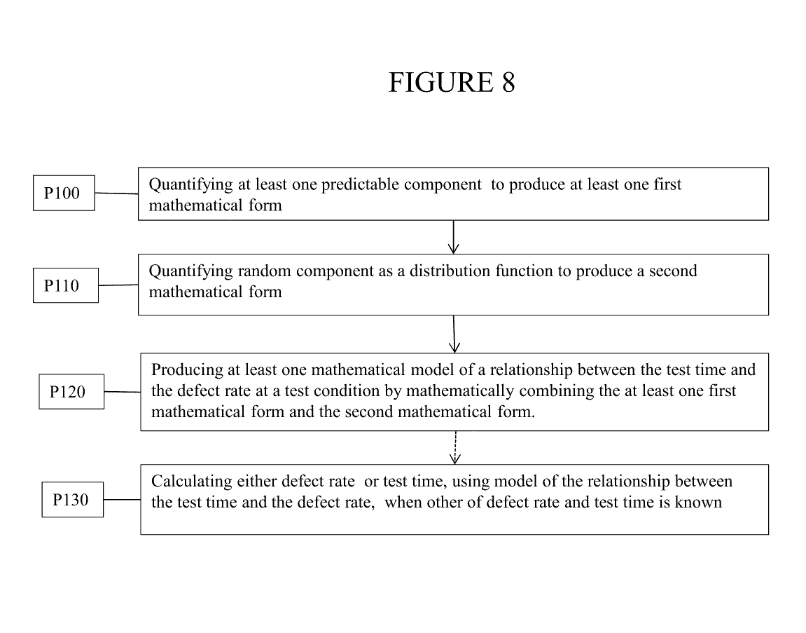

Turning now to FIG. 8, a flow diagram illustrating a method according to various embodiments is shown. The processed illustrated in FIG. 8 may be carried out by a computing device as part of a system for modeling a relationship between a test time and a defect rate for a systematic multivariate issue caused by at least one predictable component and a random component in a semiconductor testing environment, the multivariate issue causing failure of a semiconductor device. According to embodiments, the random component may be caused by electrical signal noise or the random component may be caused by an unpredictable event. Also according to embodiments, the systematic multivariate issue includes an undetected defect in the semiconductor device. The semiconductor device may include one of an n-type field-effect transistor (FET) or a p-type FET. According to embodiments, a systematic multivariate issue occurrence may be predictable and may be dependent on process sensitivity. Further, time to detect is random and in this case dependent on noise.

The occurrence of the at least one predictable component may depend on manufacturing variability, such as FET strength or wiring, which can be measured parametrically. Some examples of n-type or p-type (FET) strength include a device “on” current, a gate length, FET oxide thickness and a threshold voltage. The device “on” current may be described as a current that flows through the FET when it is operating or “turned on”. Examples of wiring variability include wiring metal capacitance and resistance.

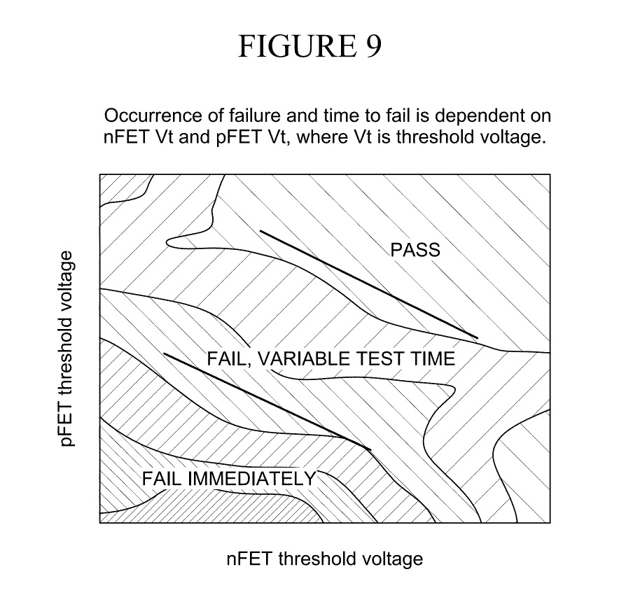

FIG. 8 illustrates process P100 which includes quantifying the at least one predictable component to produce at least one first mathematical form. The at least one first mathematical form may be a distribution function or a polynomial function. According to aspects, a predictable component may include occurrence of device failure across a process. An example of such a predictable occurrence is where device failure is linearly dependent upon NFET and PFET Vt, where Vt is threshold voltage for a transistor. This relationship is illustrated in the graph in FIG. 9.

Process P110 includes quantifying the random component as a distribution function to produce a second mathematical form. The second mathematical form may be one of a distribution function or a polynomial function, such functions may be determined empirically using the results in FIGS. 2, 3 and 4. As noted above the random component may be due to electrical signal noise. Distribution functions may be normal, log normal or other.

Process P120 includes producing a mathematical model of a relationship between the test time and the defect rate at a test condition by mathematically combining the at least one first mathematical form and the at least one second mathematical form. According to aspects, the mathematically combining of the at least one first mathematical form and the second mathematical form is performed using a Monte Carlo simulation or analysis. A test condition, according to aspects, may include one of: a speed of signal processing within the semiconductor device, a testing temperature of the semiconductor device under test, and a voltage applied to the semiconductor device under test. Other test conditions, according to aspects, may include clock frequency, and test duration.

FIG. 8 illustrates optional process P130 which includes calculating one of the defect rate and the test time, using the model of the relationship between the test time and the defect rate, in response to the other of the defect rate and the test time being known. The data illustrated in FIGS. 6 and 7 underscores this relationship. FIG. 6 illustrates that at V1, (one test condition), for a target of less than 300 DPPM, the required test time is 45 seconds. For a target of less than 200 DPPM, the required test time is 60 seconds. FIG. 7 illustrates that at a different voltage, V2, (another test condition), for a target of 500 DPPM, the required test time is above 600 seconds.

FIG. 9 shows an exemplary graph according to various embodiments. As stated above, FIG. 9 illustrates a relationship between device failure and its linear dependency upon NFET and PFET Vt, where Vt is threshold voltage for a transistor. Outcomes are shown in the same hatching scheme as illustrated by the six different schemes. Parts that fail immediately, parts that fail with a variable test time, and parts that pass are illustrated.

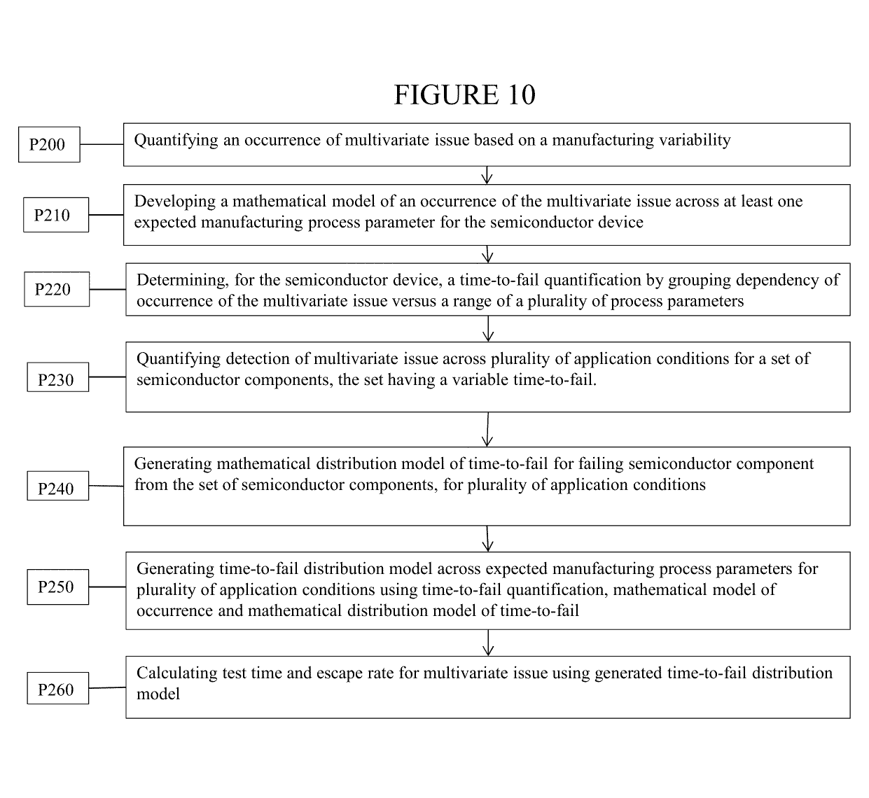

Turning now to FIG. 10, a flow diagram illustrating a method according to various aspects is shown. FIG. 10 illustrates process P200 which may be performed by at least one computing device as part of a system for calculating a test time and an escape rate for a multivariate issue in a semiconductor testing environment. The multivariate issue being caused by at least one predictable component and a random component. And the multivariate issue causing failure of a semiconductor device. According to aspects, the semiconductor device may include an n-type field-effect transistor (FET) or a p-type FET. This random component may be caused by electrical signal noise, and as discussed above, the random component may be caused by an unpredictable event

Process P200 includes quantifying an occurrence of the multivariate issue based on a manufacturing variability. The manufacturing variability may be one of a device “on” current, a gate length and a threshold voltage, or an indicator of n-type or p-type (FET) strength. The device “on” current may be described as a current that flows through the device when it is operating or “turned on”.

Process P210 includes developing a mathematical model of the occurrence of the multivariate issue across at least one expected manufacturing process parameter for the semiconductor device. Expected manufacturing process parameters may include a beta ratio, the beta ratio being equal to the value of an n-type FET (NFET) device strength divided by a value of a p-type FET (PFET) device strength, the NFET device strength and the PFET device strength being properties of components of the semiconductor device.

Process P220 includes determining, for the semiconductor device, a time-to-fail quantification by grouping dependency of occurrence of the multivariate issue versus a range of a plurality of process parameters.

Process P230 includes quantifying detection of the multivariate issue across a plurality of application conditions for a set of semiconductor components, the set of semiconductor components having a variable time-to-fail, which is related to other variables using a polynomial or exponential expression.

Process P240 includes generating a mathematical distribution model of time-to-fail for at least one failing semiconductor component from the set of semiconductor components, for the plurality of application conditions;

Process P250 includes generating a model of time-to-fail distribution across the expected manufacturing process parameters for the plurality of application conditions using the time-to-fail quantification, the mathematical model of occurrence and the mathematical distribution model of time-to-fail.

Process P260 includes calculating the test time and the escape rate for the multivariate issue using the generated model of time-to-fail distribution. This is done using the inputs above, assigning probabilities based on the distributions quantified, and relating them using the equations derived. These are then input into a statistical program which performs a Monte Carlo analysis or analytical analysis (by convolving statistical distributions), producing the output such as FIGS. 5, 6 and 7.

While shown and described herein as: a method and system modeling a relationship between a test time and a defect rate for a systematic multivariate issue caused by at least one predictable component and a random component in a semiconductor testing environment and as a system for calculating a test time and an escape rate for a multivariate issue in a semiconductor testing environment, the multivariate issue being caused by at least one predictable component and a random component it is understood that aspects of the invention further provide various alternative embodiments. For example, in one embodiment, the invention provides a computer program fixed in at least one computer-readable medium, which when executed, enables a computer system to perform a method of modeling a relationship between a test time and a defect rate for a systematic multivariate issue caused by at least one predictable component and a random component or a method of/system for calculating a test time and an escape rate for a multivariate issue in a semiconductor testing environment. To this extent, the computer-readable medium includes program code, such as calculation program 130 (FIG. 1), which implements some or all of a process described herein. It is understood that the term “computer-readable medium” comprises one or more of any type of tangible medium of expression, now known or later developed, from which a copy of the program code can be perceived, reproduced, or otherwise communicated by a computing device. For example, the computer-readable medium can comprise: one or more portable storage articles of manufacture; one or more memory/storage components of a computing device; paper; and/or the like.

In another embodiment, the invention provides a method of providing a copy of program code, which implements some or all of a process described herein. In this case, a computer system can process a copy of program code that implements some or all of a process described herein to generate and transmit, for reception at a second, distinct location, a set of data signals that has one or more of its characteristics set and/or changed in such a manner as to encode a copy of the program code in the set of data signals. Similarly, an embodiment of the invention provides a method of acquiring a copy of program code that implements some or all of a process described herein, which includes a computer system receiving the set of data signals described herein, and translating the set of data signals into a copy of the computer program fixed in at least one computer-readable medium. In either case, the set of data signals can be transmitted/received using any type of communications link.

In still another embodiment, a computer system, such as computer system 102 (FIG. 1), can be obtained (e.g., created, maintained, made available, etc.) and one or more components for performing a process described herein can be obtained (e.g., created, purchased, used, modified, etc.) and deployed to the computer system. To this extent, the deployment can comprise one or more of: (1) installing program code on a computing device; (2) adding one or more computing and/or I/O devices to the computer system; (3) incorporating and/or modifying the computer system to enable it to perform a process described herein; and/or the like.

It is understood that aspects of the invention can be implemented as part of a business method that performs a process described herein on a subscription, advertising, and/or fee basis. That is, a service provider could offer to perform calculations as described herein. In this case, the service provider can manage (e.g., create, maintain, support, etc.) a computer system, such as computer system 102 (FIG. 1), that performs a process described herein for one or more customers. In return, the service provider can receive payment from the customer(s) under a subscription and/or fee agreement, receive payment from the sale of advertising to one or more third parties, and/or the like.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal languages of the claims.

What is claimed is:

1. A system for modeling a relationship between a test time and a defect rate for a systematic multivariate issue caused by at least one predictable component and a random component in a semiconductor testing environment, the multivariate issue causing failure of a semiconductor device, the system comprising:
at least one computing device configured to perform actions including:
quantifying the at least one predictable component to produce at least one first mathematical form;
quantifying the random component using distribution functions to produce a second mathematical form; and
producing a mathematical model of a relationship between the test time and the defect rate at a test condition by mathematically combining the at least one first mathematical form and the second mathematical form.

2. The method of claim 1 wherein the mathematically combining of the at least one first mathematical form and the second mathematical form is performed using a Monte Carlo simulation.

3. The method of claim 1, wherein the at least one first mathematical form is one of a distribution function or a polynomial function and the second mathematical form is one of a distribution function or a polynomial function.

4. The method of claim 1, further comprising:
calculating one of the defect rate and the test time, using the model of the relationship between the test time and the defect rate, in response to the other of the defect rate and the test time being known.

5. The method of claim 1, wherein the systematic multivariate issue includes an undetected defect in the semiconductor device.

6. The method of claim 1, wherein the random component is caused by electrical signal noise.

7. The method of claim 1, wherein the semiconductor device includes one of an n-type field-effect transistor (FET) or a p-type FET, and
wherein an occurrence of the at least one predictable component depends on manufacturing variability as measured by one of a device on current, a gate length a threshold voltage, an FET strength, an FET oxide thickness, a wiring resistance or a wiring capacitance.

8. The method of claim 1, wherein the test condition includes one of: a speed of signal processing within the semiconductor device, a testing temperature of the semiconductor device under test, and a voltage applied to the semiconductor device under test.

9. A computer program product comprising program code stored on a computer-readable storage medium, which when executed by at least one computing device, enables the at least one computing device to implement a method of modeling relationship between a test time and a defect rate for a systematic multivariate issue caused by at least one predictable component and a random component in a semiconductor testing environment, the multivariate issue causing failure of a semiconductor device, configured to perform actions including:
quantifying the at least one predictable component to produce at least one first mathematical form;
quantifying the random component using distribution functions to produce a second mathematical form; and
producing a mathematical model of a relationship between the test time and the defect rate at a test condition by mathematically combining the at least one first mathematical form and the second mathematical form.

10. The computer program product of claim 9, wherein the mathematically combining of the at least one first mathematical form and second mathematical forms is performed using a Monte Carlo simulation.

11. The computer program product of claim 9, wherein first mathematical form is one of a mathematical distribution or a mathematical function and the second mathematical form is one of a mathematical distribution or a mathematical function.

12. The computer program product of claim 9, further comprising:
calculating one of the defect rate and the test time, using the model of the relationship between the test time and the defect rate, in response to the other of the defect rate and the test time being known.

13. The computer program product of claim 9, wherein the systematic multivariate issue includes an undetected defect in a processed semiconductor device.

14. The computer program product of claim 9, wherein the random component is caused by electrical signal noise.

15. The computer program product of claim 9, wherein the semiconductor device includes one of an n-type field-effect transistor (FET) or a p-type FET, and
wherein an occurrence of the at least one predictable component depends on manufacturing variability as measured by one of a device on current, a gate length a threshold voltage, an FET strength, an FET oxide thickness, a wiring resistance or a wiring capacitance.

16. The computer program product of claim 9, wherein the target testing condition includes one of: a speed of signal processing within the semiconductor device, a testing temperature of the semiconductor device under test and a voltage applied to the semiconductor device under test.

17. A system for calculating a test time and an escape rate for a multivariate issue in a semiconductor testing environment, the multivariate issue being caused by at least one predictable component and a random component, the multivariate issue causing failure of a semiconductor device, the system comprising:
at least one computing device configured to perform actions including:
quantifying an occurrence of the multivariate issue based on a manufacturing variability;
developing a mathematical model of the occurrence of the multivariate issue across at least one expected manufacturing process parameter for the semiconductor device;
determining, for the semiconductor device, a time-to-fail quantification by grouping dependency of occurrence of the multivariate issue versus a range of a plurality of process parameters;
quantifying detection of the multivariate issue across a plurality of application conditions for a set of semiconductor components, the set of semiconductor components having a variable time-to-fail and a variable time-to-fail dependency;
generating a mathematical distribution model of time-to-fail for at least one failing semiconductor component from the set of semiconductor components, for the plurality of application conditions;
generating a model of time-to-fail distribution across the expected manufacturing process parameters for the plurality of application conditions using the time-to-fail quantification, the mathematical model of occurrence and the mathematical distribution model of time-to-fail; and
calculating the test time and the escape rate for the multivariate issue using the generated model of time-to-fail distribution.

18. The system of claim 17, wherein the semiconductor device includes one of an n-type field-effect transistor (FET) or a p-type FET, and
wherein the manufacturing variability is one of a device on current, a gate length a threshold voltage, an FET strength, an FET oxide thickness, a wiring resistance or a wiring capacitance.

19. The system of claim 17, wherein the expected manufacturing process parameters include a beta ratio, the beta ratio being equal to the value of an n-type FET (NFET) device strength divided by a value of a p-type FET (PFET) device strength, the NFET device strength and the PFET device strength being properties of components of the semiconductor device.

20. The system of claim 17, wherein the random component is caused by electrical signal noise.
